(19) United States
(12) Patent Application Publication
(10) Pub. No.: US 2005/0101138 A1
(43) Pub. Date: May 12, 2005

(54) System and method for applying constant pressure during electroplating and electropolishing

(76) Inventors: George Xinsheng Guo, Palo Alto, CA (US); Bulent M. Basol, Manhattan Beach, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/984,272

(22) Filed: Nov. 8, 2004

Related U.S. Application Data
(60) Provisional application No. 60/518,079, filed on Nov. 7, 2003.

(51) Int. Cl. B24B 1/00; B24B 7/19; B24B 7/30; H01L 21/302; H01L 21/461

(52) U.S. Cl. 438/689

(57) ABSTRACT

A system and method for processing a surface of a semiconductor workpiece. The system comprises a workpiece surface influencing device, a workpiece carrier, and an electrode. The workpiece surface influencing device has an abrasive processing surface and is magnetically biased toward the workpiece surface to be processed. The workpiece surface influencing device has a plurality of openings through which process solution may flow to wet the surface of a workpiece to be processed. Conductive material may be either deposited on the workpiece surface or removed from the workpiece surface. The system may include an electrical contact touching the workpiece and an electrode immersed in processing solution for electrochemically processing the workpiece surface.

### RELATED APPLICATION

This application claims priority from U.S. Provisional Application No. 60/518,079, filed Nov. 7, 2003.

### FIELD

The present invention generally relates to semiconductor integrated circuit technology and, more particularly, to electrotreating or electrochemical processing techniques, such as electroplating and electroetching, that are applied to the surface of a workpiece.

### BACKGROUND

Conventional semiconductor devices, such as integrated circuits (IC), generally comprise a semiconductor substrate, which is typically a silicon substrate, and a plurality of sequentially formed conductive material layers separated by insulating material layers. Conductive material layers, or interconnects, form the wiring network of the integrated circuit. This wiring network is isolated from neighboring wiring networks by insulating layers or the interlayer dielectrics. One dielectric material that is commonly used in silicon integrated circuits is silicon dioxide, although there is currently a trend to replace at least some of the standard dense silicon dioxide material in the IC structure with low-k dielectric materials. This replacement is desirable in high-performance ICs where the RC time constant needs to be reduced to increase the speed of the circuit. In order to reduce the capacitance, it is desirable to replace the high dielectric constant materials in the interconnect structure with low-k materials.

Conventionally, IC interconnects are formed by filling a conductor, such as copper, in features or cavities that are etched into the dielectric interlayers by a metallization process. Copper is becoming the preferred conductor for interconnect applications because of its low electrical resistance and good electromigration property. The preferred method of copper metallization process is electroplating.

In an integrated circuit, multiple levels of interconnect networks laterally extend with respect to the substrate surface. Interconnects formed in sequential layers can be electrically connected using features formed in the insulating layer, such as vias or contacts. In a typical interconnect fabrication process, an insulating layer is first formed on the semiconductor substrate. Patterning and etching processes are then performed to form features or cavities, such as trenches, vias, and pads etc., in the insulating layer. Copper is then electroplated to fill all of the features. In such electroplating processes, the substrate is typically placed on a substrate carrier and a cathodic (−) voltage with respect to an electrode is applied to the substrate surface while an electrolyte or the electrolyte solution wets both the substrate surface and the electrode.

Once the plating process is completed, a material removal step, such as a chemical mechanical polishing (CMP) process step, is conducted to remove an excess copper layer, which is sometimes referred to as copper overburden, from the top surfaces (also called field region) of the substrate, leaving copper only in the features. An additional material removal step is then employed to remove other conductive layers such as barrier/glue layers that are on the field region. Copper deposits within features are therefore both physically and electrically isolated from each other. It should be noted that material removal techniques include, but are not limited to, CMP, electroetching or electropolishing, and chemical etching techniques. Furthermore, approaches that can remove both copper and the barrier/glue layers from the field region in one step may also be used.

During the CMP step, the plated substrate surface is pressed against a polishing pad or a polishing belt and planarized while the substrate is rotated and/or the pad is moved. As indicated above, this process electrically isolates the copper deposited into various features on a given interconnect level after removing the excess copper and the barrier layer from the field regions. After repeating these processes several times, multi-level interconnect structures may be formed, in which copper within vias or other contact features may electrically connect the various interconnect levels.

Although the CMP processes can be easily used with the conventional interlayer dielectrics, they may create problems with ultra-low-k dielectrics because of the mechanical force applied by the CMP pad on the substrate surface during the CMP process. If subjected to a CMP step, low-k materials may be stressed and may delaminate, or other defects may form due to the low mechanical strength and poor adhesion of low-k materials. These problems become more prominent with longer CMP process times. Therefore, it is desirable to reduce or eliminate CMP time as well as force on substrates, especially those having low-k insulators.

The adverse effects of conventional material removal technologies may be minimized or overcome by employing an Electrochemical Mechanical Processing (ECMPR) approach that has the ability to provide a thin layer of planar conductive material on the substrate surface, or even provide a substrate surface with no or little excess conductive material. The term Electrochemical Mechanical Processing (ECMPR) is used to include both Electrochemical Mechanical Deposition (ECMD) as well as Electrochemical Mechanical Etching (ECME), which is also referred to as Electrochemical Mechanical Polishing (ECMP).

Descriptions of various planar deposition and planar etching methods for selectively depositing conductive material in and over cavity sections on a substrate in a planar manner or for removing and planarizing layers, i.e. ECMPR approaches and apparatuses, can be found in the following patents and pending applications: U.S. Pat. No. 6,176,992, entitled “Method and Apparatus for Electro-chemical Mechanical Deposition,” U.S. Pat. No. 6,534,116, entitled “Plating Method and Apparatus that Creates a Differential Between Additive Disposed on a Top Surface and a Cavity Surface of a Workpiece Using an External Influence,” and U.S. patent application Ser. No. 09/961,193, filed on Sep. 20, 2001, entitled “Plating Method and Apparatus for Controlling Deposition on Predetermined Portions of a Workpiece,” U.S. patent application Ser. No. 09/960,236, filed on Sep. 20, 2001, entitled “Mask Plate Design,” and U.S. patent application Ser. No. 10/155,828, filed on May 23, 2002, entitled “Low Force Electrochemical Mechanical Processing Method and Apparatus.” All of the foregoing patents and patent applications are hereby incorporated herein by reference in their entireties.

FIG. 1 shows an exemplary conventional ECMPR system 10, which includes a workpiece-surface-influencing device (WSID) 12, such as a mask, pad or a sweeper, a carrier head 14 holding a substrate 16 or wafer, and an electrode 18. The substrate 16 can be, for example, a silicon wafer to be plated with copper using the ECMPR system 10, or it can be a copper plated wafer to be electropolished using the ECMPR system 10. The WSID 12 is used during at least a portion of the ECMPR when there is physical contact or close proximity and relative motion between a surface 20 of the substrate 16 and the WSID 12. A surface 22 of the WSID 12 sweeps the surface 20 of the substrate 16. Electrical contact with the surface 20 of the substrate 16 is established through contacts touching the edge of the substrate 16.

As shown in FIG. 1, channels 24 or openings of the WSID 12 allow a process solution 26, such as a copper electrolyte or etching solution, to flow to the surface 20 of the substrate 16. The channels 24 may have varying sizes and shapes to control the uniformity of the planar layer that is being deposited on or removed from the surface 20 of the substrate 16. The WSID 12 typically comprises a top layer 28, which is formed of a flexible film, and a compressible layer 30 that is formed of a spongy and compressible material. It will be appreciated that the top layer 28 may be an abrasive film. The WSID 12 typically is supported by a rigid support plate 32, as shown in FIG. 1.

If the ECMD process is carried out to plate copper onto the substrate 16 in the ECMPR system 10, the surface 20 of the substrate 16 is wetted by a deposition electrolyte, which is also in fluid contact with the electrode (anode) 18. A potential is applied between the surface 20 of the substrate 16 and the electrode 18, rendering the substrate surface 20 cathodic.

If the ECMP process is carried out to remove material from the substrate 16, the surface 20 of the substrate 16 is wetted by an etching electrolyte, which is in fluid contact with the electrode (cathode during the etching) 18 and a potential is applied between the surface 20 of the substrate 16 and the electrode 18, rendering the substrate surface 20 anodic. Thus, etching or material removal takes place on the substrate surface 20.

The ECMPR systems are capable of performing planar or non-planar plating as well as planar or non-planar electropolishing. For example, if a non-planar process approach is chosen, the surface 20 of the substrate 16 is brought into proximity of the surface 22 of the WSID 12, but it does not touch it, so that non-planar deposition can be performed.

Further, if a planar process approach is chosen, the surface 20 of the substrate 16 contacts the WSID surface 22 as a relative motion is established between the WSID surface 22 and the substrate surface 20. As the electrolyte solution 26 is delivered, as depicted by arrows, through the channels 24 of the WSID 12, the substrate 16 is moved, e.g., rotated and laterally moved, while the surface 20 contacts the WSID 12. Under an applied potential between the substrate 16 and the electrode 18, and in the presence of the solution 26 that rises through the channels 24 of the WSID 12, the conductive material, which may be, for example, copper, is plated on or etched off the surface 20 of the substrate 16, depending on the polarity of the voltage applied between the substrate surface 20 and the electrode 18. During the process, the substrate surface 20 is pushed against the surface 22 of the WSID 12 or vice versa, at least during part of the process time, while the surface 20 of the substrate 16 is swept by the WSID 12. Deposition of a thin and planar layer is achieved due to the sweeping action of the WSID 12.

However there are problems with current WSID materials, especially the spongy material 30. The dimensions of the spongy material 30 typically changes in time, as it is soaked by process solutions 26 that are used in the process. This dimensional change will change the amount of actual compression during processing, and as a result substrate uniformity during plating or removal is affected. The spring constant of the spongy material 30 also changes over time. A change in spring constant reduces the force applied to the substrate surface 20 by the compressed spongy material 30. Adding to these problems, there is a sharp bending of the spongy material layer 30 at the substrate 16 edge. This sharp bending typically increases the amount of wearing on the corresponding location of the top abrasive layer 28 when the substrate 16 is moved against the WSID 12. In addition, the abrasive layer 28 can be broken if the abrasive is formed of a fragile material or a less flexible material. Such problems affect the process consistency, especially when a number of substrates are processed. For example, with the changing compressive force of the spongy material 30, thickness uniformity of a deposited or etched layer on substrates 16 may differ from substrate to substrate and/or batch to batch.

Consequently, the lifetime of the spongy material 30, and hence the lifetime of the WSID 12 containing it, is limited and the WSID needs to be replaced often in order to achieve process consistency.

To this end, there is a need for an improved method and apparatus for maintaining the uniformity of the plated or etched layer during planar metal deposition or electroetching.

### SUMMARY

In accordance with one aspect of the invention, a system is provided for processing a surface of a semiconductor workpiece. The system comprises a workpiece holder configured to hold the workpiece, a processing structure, and at least one biasing member in the processing structure. The processing structure has a processing surface, and is positioned across from a surface of the workpiece holder. The at least one biasing member comprises a magnetic material placed behind the processing surface, and is configured to bias the processing surface toward the surface of the workpiece during processing.

In accordance with another aspect of the invention, a method is provided for electrochemically processing a conductive material on a surface of a workpiece. The method comprises polishing the surface with a polishing structure while magnetically biasing the polishing structure toward the surface of the workpiece, and touching the surface with at least one electrical contact while maintaining relative motion between the surface and the polishing structure during polishing.

In accordance with yet another aspect of the invention, a method is provided for processing a conductive material on a surface of a semiconductor workpiece. The method comprises polishing the surface of the semiconductor workpiece and magnetically biasing the processing structure toward the semiconductor workpiece while polishing. The surface of the semiconductor workpiece is polished with a processing structure while maintaining relative motion between the surface of the semiconductor workpiece and the processing structure.

### BRIEF DESCRIPTION OF THE DRAWINGS

These and other aspects of the invention will be readily apparent to those skilled in the art in view of the description below, the appended claims, and from the drawings, which are intended to illustrate and not to limit the invention, and wherein:

FIG. 1 is a schematic side cross-sectional view of a conventional electrochemical mechanical processing system using a conventional workpiece surface influencing device;

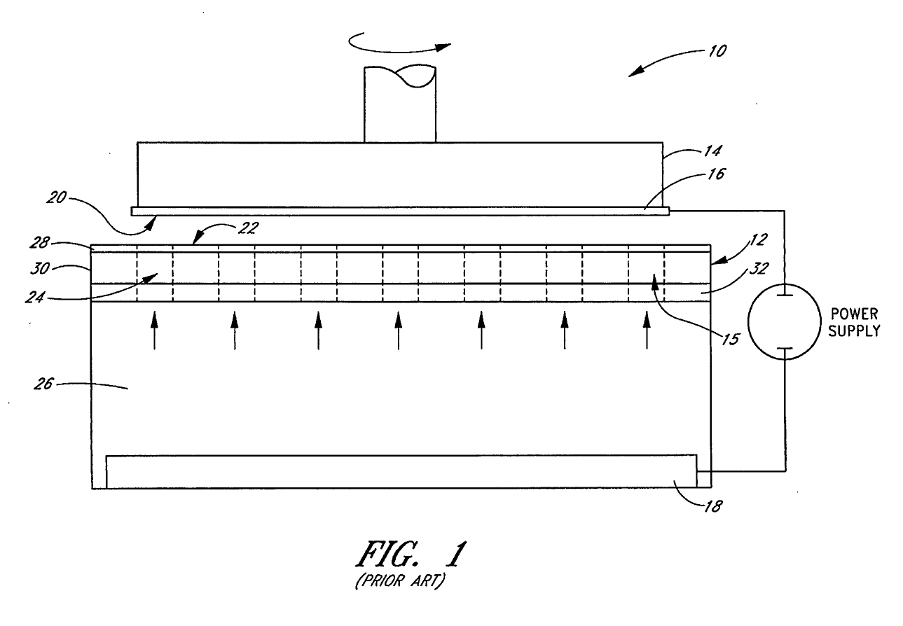

FIG. 2 is a schematic side cross-sectional view of an electrochemical mechanical processing system using an embodiment of a processing structure; and

FIG. 3 is a schematic side cross-sectional view of an electrochemical mechanical processing system of another embodiment of the processing structure.

### DETAILED DESCRIPTION

The following detailed description of the preferred embodiments and methods presents a description of certain specific embodiments to assist in understanding the claims. However, one may practice the present invention in a multitude of different embodiments and methods as defined and covered by the claims.

It will be appreciated that the apparatuses may vary as to configuration and as to details of the parts, and that the methods may vary as to the specific steps and sequence, without departing from the basic concepts as disclosed herein.

The preferred embodiments of the present invention are described in the context of fabricating interconnects for integrated circuit applications. However, it should be understood that embodiments of the present invention can be used to fill in cavities on any workpiece with various electroplated materials, including, but not limited to, Au, Ag, Ni, Pt, Pd, Fe, Sn, Cr, Pb, Zn, Co and their alloys, with each other or other materials, for many different applications, including, but not limited to, packaging, flat panel displays, and magnetic heads. In one embodiment, for example, a planar conductive layer on a workpiece is processed, e.g., electroplated or electropolished by an ECMPR process using a workpiece-surface-influencing device structure (or processing structure) according to an embodiment, which applies a uniform force to the surface of the workpiece being processed.

The present invention provides a system and a method for applying a processing structure on a workpiece surface during processing of the workpiece surface. In preferred embodiments, examples of processing structures may be a WSID configured to mechanically contact and sweep a surface of a workpiece during an ECMPR or a CMP pad to be used during a CMP process. The processing structure may be biased towards the workpiece surface using a biasing mechanism. Examples of biasing mechanisms include, but are not limited to, a mechanical biasing mechanism, a magnetic biasing mechanism, and a mechanism using fluid pressure.

A mechanical biasing mechanism may use various mechanical approaches to bias a surface of the processing structure towards the workpiece surface and apply pressure on the workpiece surface. Exemplary mechanical biasing mechanisms use, for example, springs to push the processing structure against the workpiece surface, spongy material in the processing structure to generate pressure on the workpiece surface, or fluid pressure to push the processing structure against the workpiece surface. For example, U.S. Pat. No. 6,471,847, entitled “Method For Forming An Electrical Contact With A Semiconductor Substrate,” describes a WSID or a pad biased toward a workpiece using springs. The biased pad is used for ECMD or ECMP processes. U.S. patent application Ser. No. 10/155,828, filed May 23, 2002, entitled “Low Force Electrochemical Mechanical Deposition Method and Apparatus,” describes the use of spongy material in a WSID structure to apply force on a workpiece surface when the workpiece surface is pressed onto a surface of the WSID. In this case, compressed spongy material layer applies a uniform force onto the workpiece surface during the process. U.S. patent application Ser. No. 10/288,558, filed Nov. 4, 2002, entitled “Electrochemical Mechanical Deposition with Advancible Sweeper,” describes the use of fluid pressure, such as the pressure of process solution, with or without help of auxiliary mechanical means, to push a WSID against a workpiece surface. Use of fluid pressure, such as pressure from gases in CMP systems to push a CMP polishing pad onto a workpiece surface for material removal purposes is also described in U.S. patent application Ser. No. 10/105,016, filed Mar. 22, 2002, entitled “Chemical Mechanical Polishing Apparatus and Methods Using a Flexible Pad and Variable Fluid Flow for Variable Polishing,” and U.S. patent application Ser. No. 10/346,425, filed Jan. 17, 2003, entitled “Advanced Chemical Mechanical Polishing System with Smart Endpoint Detection.” The entire disclosures of the foregoing patents and patent applications are hereby incorporated herein by reference.

As will be described in more detail below, preferred embodiments of the present invention use magnetic force to apply a globally uniform or localized pressure onto a workpiece surface, such as a semiconductor wafer surface, that is being processed by a material deposition or removal process. A material deposition process may be, for example, an ECMD process, and a material removal process may be, for examples, either an ECMP process or a CMP process. During such processes, a processing structure, such as a WSID or a CMP pad, is magnetically biased towards the workpiece surface that is processed.

The magnetic bias may be produced by forming a first magnetic structure under the processing structure and a second magnetic structure behind a workpiece that is being processed. The second magnetic structure may be placed in a workpiece carrier head, such as a location that is adjacent a back surface of the workpiece. During the process, as the first and second magnetic structures are magnetically attracted to one another, the processing structure is moved towards the surface of the workpiece that is being processed and provides the required pressure on the workpiece surface that is being processed.

In this respect, the first and second magnetic structures are preferably formed of magnetic materials that can be magnetically attracted to one another with a constant force. It will be appreciated that, in an alternative embodiment, one of the first magnetic structure or second magnetic structure may be formed of a magnetic material that has permanent magnetic properties and the other one may be formed of a material that can be attracted by such magnetic material. In still another embodiment, one of the magnetic structures may be formed of a material having electromagnetic properties. Such materials having electromagnetic properties gain magnetic properties when an electrical current is applied upon it. For example, the first magnetic structure may be formed of a single material piece, such as a plate or film. Alternatively, the first magnetic structure may be formed of a plurality of material pieces that are either placed side by side or stacked on top of each other. Similarly, the second magnetic structure, which may be placed behind the workpiece, may be formed of a single material piece, such as a plate or film, or alternatively formed of more than one material piece placed side by side or stacked on top of each other.

Alternatively, the first and second magnetic structures may be formed of multiple components configured to apply localized pressure on various regions of the surface of the workpiece to be processed, thereby magnetically attracting a certain region of the processing structure towards the surface of the workpiece by magnetically activating the magnetic components of the processing structure that correspond to the region where the localized pressure is required.

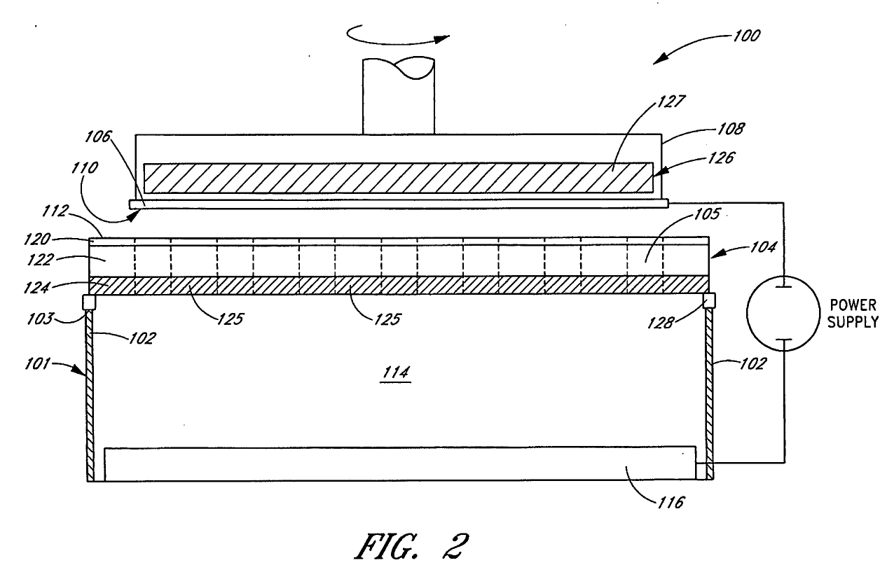

FIG. 2 is a schematic side view illustration of an ECMPR system 100 of a preferred embodiment of the present invention. The system 100 includes a process chamber 101 with side walls 102. A WSID 104 having openings 105 is placed on upper ends 103 of the side walls 102. A workpiece 106 to be processed is held in proximity of the WSID 104 preferably by a wafer carrier 108. The WSID 104 is preferably movably attached to the upper ends 103 of the side walls 102.

The workpiece 106 may be a silicon wafer to be processed by selectively plating a conductive material layer over a surface 110 of the workpiece 106. Alternatively, the workpiece 106 may be a silicon wafer plated with a conductive material to be removed. Those skilled in the art will appreciate that if a CMP system is used to process the workpiece 106, the workpiece surface 110 may be any material, either conductive or non-conductive. If the workpiece surface 110 is conductive, the conductive material may preferably be copper or a copper alloy.

The workpiece 106 is preferably retained by the workpiece carrier 108 during the process. The workpiece carrier 108 may rotate and move the workpiece 106 laterally or vertically. The workpiece carrier 108 positions the surface 110 of the workpiece 106 against a surface 112 of the WSID 104 during ECMPR. Openings 105 in the WSID 104 are configured to allow a process solution 114, such as an electroplating, electropolishing, or etching solution, to flow through the WSID 104 and onto the surface 110 of the workpiece 106 during an electroplating or polishing process. The openings 105 may be shaped as holes with different geometries or slits.

A preferred embodiment of the ECMPR system 100 also includes an electrode 116, which is preferably immersed in the process solution 114. The process solution 114 wets the electrode 116 as well as the surface 110 of the workpiece 106. The surface 112 of the WSID 104 preferably sweeps the surface 110 of the workpiece 106 during the ECMPR. An electrical potential is established between the electrode 116 and the surface 110 of the workpiece 106 while a relative motion between the workpiece 106 and the WSID 104 is established.

If an ECMD process is carried out to selectively deposit a conductive material over the surface 110 of the workpiece 106, the surface 110 of the workpiece is wetted by a process solution 114, such as a deposition electrolyte, which is in fluid contact with the electrode 116. It is to be understood that, in the case of ECMD, the electrode 118 is an anode. A potential is applied between the workpiece surface 110 and the electrode 118, thereby rendering the workpiece surface 110 cathodic.

If an ECMP process is carried out to remove material from the workpiece surface 110, the surface 110 is wetted by the process solution 114, such as an etching electrolyte, which is in fluid contact with the electrode 118. It is to be understood that, in the case of ECMP, the electrode 118 is a cathode. A potential is applied between the workpiece surface 110 and the electrode 118, thereby rendering the workpiece surface 110 anodic.

In this embodiment, the WSID 104 is preferably comprised of a top layer 120, an intermediate layer 122, and a bottom layer 124. The top layer 120 may include a polishing layer, which is preferably formed of a flexible or non-flexible abrasive film, and the intermediate layer 122 may be a compressible layer, which is preferably formed of a spongy or compressible material, such as polyurethane. The bottom layer 124 may be a magnetic layer, preferably comprising a first magnetic structure 125, and is attached to the compressible layer 122.

The first magnetic structure 125 may be formed of a magnetic material having permanent magnetic properties, such as those of a permanent magnet, or a material that is magnetized when exposed to a magnetic field. In this embodiment, the first magnetic structure 125 is preferably formed of a permanent magnet. Although in this embodiment, the WSID 104 includes a compressible material layer 122, the use of compressible material in this WSID 104 embodiment is optional. Accordingly, the first magnetic structure 125 may be directly attached to the polishing layer 120. The magnetic bottom layer 124 may be formed as a single piece film, sheet, or plate that is formed of the first magnetic material, or may be formed of more than one piece for example a plurality of pieces formed as strips or pieces having same or differing dimensions. The pieces may be laterally aligned side by side to form the magnetic layer 124.

The WSID 104 may be placed on a rigid support layer (not shown), which is preferably formed of an insulating material. Alternatively, the magnetic layer 124 may take over the support functions of the support layer and a support layer may not be needed. The openings 105 of the WSID 104 are preferably continuous through the layers 120, 122, 124 if provided through a support layer. It should be understood that the WSID 104 is laterally continuous, as FIG. 2 is a schematic side cross-sectional view of an embodiment.

Preferably, the WSID 104 is movably attached to the upper end 103 of the process chamber 101. As shown in FIG. 2, the WSID 104 may be attached to the upper end 103 of the process chamber 101 by the magnetic layer 124. Alternatively, if there is a support layer (not shown) supporting the magnetic layer 124, the WSID 104 may be attached to the upper end 103 of the process chamber 101 by the support layer (not shown).

Movable members 128 that allow the WSID 104 to move vertically can be used to attach the WSID 104 to the upper end 103 of the chamber 101. Movable members 128 may be, for example, springs, bellows, hinges or rails, which allow the WSID 104 to move vertically. Alternatively, the WSID 104 may simply float on the process solution 114. In another approach, if the magnetic structure 125 is attached to the polishing layer 120, the WSID 104 may be directly attached to the upper end 103 of the process chamber 101.

The carrier head 108 preferably includes a magnetic member 126, which is supported in a location behind the workpiece 106, as shown in FIG. 2. This location may be, for example, on a chuck face on the carrier head 108, which holds the workpiece 106.

The magnetic member 126 is preferably formed of a second magnetic material 127. The second magnetic material 127 may be formed of a magnetic material having permanent magnetic properties, such as those of a permanent magnet or a material that is magnetized when exposed to a magnetic field. In this embodiment, the second magnetic material 127 is preferably formed of a permanent magnet. The magnetic member 126 may be formed as a single film, sheet or plate of the second magnetic material 127, or may be formed of more than one piece. For example, the magnetic member may comprise a plurality of second magnetic material pieces formed as strips or pieces having the same or differing dimensions. For example, the pieces may be laterally aligned side by side to form the magnetic member. Alternatively, the second magnetic material may be an electromagnetic material, e.g. electromagnet, that gains magnetic properties when an electrical current is applied. Those skilled in the art will appreciate that if electromagnetic materials are used to form a magnetic member with multiple components or sections, in which each section or component can be magnetized independently, localized processing of the surface 110 of the workpiece 106 may be achieved.

In accordance with an embodiment, during processing of the surface 110 of the workpiece 106, as contact is established between the surface 110 of the workpiece 106 and the surface 112 of the WSID 104, the magnetic member 126 and the magnetic layer 124 of the WSID 104 are magnetically attracted to one another. With this magnetic force, the surface 112 of the WSID 104 moves towards the surface 110 of the workpiece 106 and presses against the surface 110 of the workpiece 106. As a result, the surface 112 of the WSID 104 uniformly contacts the surface 110 of the workpiece 106 and uniformly processes the surface 110 of the workpiece 106 as the process solution 114 flows through the WSID 104. It is to be appreciated that the magnetic bias described herein may be achieved with any type of suitable magnetic materials and arrangement of such magnetic materials.

In preferred embodiments of the ECMPR system 100, the force applied by the WSID 104 does not change over time because the magnetic bias allows the WSID 104 to uniformly contact the workpiece surface 110. The force applied by the WSID 104 on the workpiece 106 drops off gradually near the workpiece 106 edge. The magnetic bias also reduces sharp bending of the layer 122 of compressible material near the workpiece 106 edge. The reduction of the sharp bending reduces the amount of wear on the top layer 120 of the WSID 104. Preferred embodiments of the system 100 also make it easier to optimize the pressure across the workpiece 106. The lifetime of the WSID 104 may be unlimited if the magnetic structure 125 is shielded from corrosion.

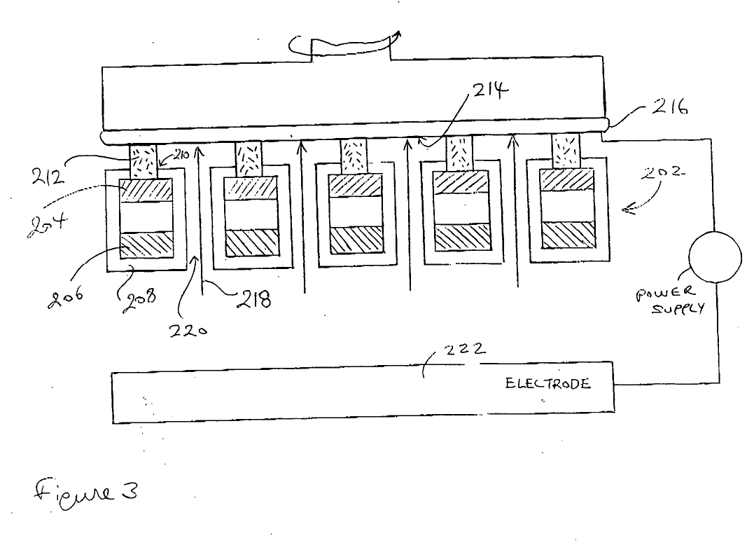

FIG. 3 is a schematic side view illustration of an alternative embodiment of an ECMPR system 200. In this embodiment, a processing structure 202 includes a first magnetic structure 204 and a second magnetic structure 206. The first and second magnetic structures 204, 206 of the processing structure 202 can be permanent magnet bars with their like poles placed facing each other in a casing 208 including an opening 210. As such, a produced repulsing force levitates the first magnetic structure 204 above the second magnetic structure 206. A pad 212 is attached to the first magnetic structure 204 and extends through the opening 210. The first magnetic structure 204 can move vertically in the casing 208 when a surface 214 of a wafer 216 is pressed against the pad 212, thereby keeping the pad 212 biased towards the surface 214. A process solution 218 flows through openings or gaps 220 among the casings 208 and touches both an electrode 222 and the surface 214 of the wafer 216, which is preferably held by a wafer carrier 224. In this embodiment, the wafer carrier 224 may not have a magnetic structure. In this embodiment, the first and second magnetic structures 204, 206 may be in the form of elongated bars. However, it is understood that they may have any shape and/or geometry.

Although various preferred embodiments have been described in detail above, those skilled in the art will readily appreciate that the present invention extends beyond the specifically disclosed embodiments to other alternative embodiments and/or uses of the invention and obvious modification thereof without materially departing from the novel teachings and advantages of this invention. Thus, it is intended that the scope of the present invention herein disclosed should not be limited by the particular disclosed embodiments described above, but should be determined only by a fair reading of the claims that follow.

1. A system for processing a surface of a semiconductor workpiece, comprising:
a workpiece holder configured to hold the workpiece;
a first magnetic structure placed in the workpiece holder;
a processing structure having a processing surface, the processing structure positioned across from a surface of the workpiece; and
a second magnetic structure placed in the processing structure and configured to bias the processing surface toward the surface of the workpiece during processing.

2. The system of claim 1, wherein the processing structure has a plurality of openings therethrough configured to allow processing solution to flow through the openings to the surface of the workpiece.

3. The system of claim 1, wherein at least one of the first magnetic structure and the second magnetic structure is a permanent magnet.

4. The system of claim 1, wherein the first magnetic structure is a permanent magnet and the second magnetic structure is an electromagnet.

5. The system of claim 4, wherein the electromagnet is comprised of a plurality of sections.

6. The system of claim 5, wherein each of the plurality of sections is connected to a separate power source.

7. The system of claim 1, wherein the processing structure is supported by a support plate.

8. The system of claim 1, wherein the processing structure is supported by the second magnetic structure.

9. The system of claim 8, wherein the processing structure is placed on movable members so as to allow the processing structure to move towards or away from the surface of the workpiece.

10. The system of claim 1, wherein the processing surface is a polishing pad.

11. The system of claim 1, wherein the processing surface is abrasive.

12. The system of claim 11, wherein the first magnetic structure comprises a bottom layer of the processing structure.

13. The system of claim 12, wherein the processing structure further comprises an intermediate layer positioned between the top layer and the bottom layer, the intermediate layer being formed of a compressible material.

14. The system of claim 1, further comprising an electrode immersed in process solution, the electrode being positioned on a side of the processing structure opposite the workpiece holder.

15. The system of claim 14, wherein an electrical potential is applied between the surface of the workpiece and the electrode.

16. The system of claim 14, further comprising an electrical contact touching the surface of the semiconductor workpiece.

17. A method of electrochemically processing a conductive material on a surface of a workpiece, comprising:
polishing the surface with a polishing structure while magnetically biasing the polishing structure toward the surface of the workpiece; and
touching the surface with at least one electrical contact while maintaining relative motion between the surface and the polishing structure during polishing.

18. The method of claim 17, wherein the magnetically biasing results in applying a selected pressure to the surface of the workpiece by the polishing structure.

19. The method of claim 17, wherein the magnetically biasing results in applying a selected pressure to a region of the surface of the workpiece.

20. The method of claim 17, wherein the magnetically biasing results in applying a selected pressure to a region of the surface of the workpiece while applying another selected pressure to another region of the surface of the workpiece.

21. The method of claim 17, further comprising establishing a relative motion between the at least one electrical contact and the workpiece.

22. The method of claim 17, wherein at least some of the conductive material is removed from the surface during polishing.

23. The method of claim 17, wherein at least some of the conductive material is selectively deposited on the surface during polishing.

24. The method of claim 23, wherein the conductive material is deposited as a planar layer.

25. The method of claim 17, wherein the polishing structure has a top layer formed of an abrasive material.

26. The method of claim 17, wherein the polishing structure has a bottom layer formed of a magnetic material configured to magnetically bias the polishing structure toward the surface of the workpiece.

27. The method of claim 17, wherein the polishing structure has a plurality of openings configured to allow processing solution to flow therethrough to the surface of the workpiece.

28. The method of claim 27, wherein the processing solution contains a copper electrolyte.

29. The method of claim 27, wherein the processing solution is in fluid contact with an electrode.

30. The method of claim 27, wherein the processing solution is an etching solution.

31. A method of processing a conductive material on a surface of a semiconductor workpiece, comprising:
polishing the surface of the semiconductor workpiece with a processing structure while maintaining relative motion between the surface of the semiconductor workpiece and the processing structure; and
magnetically biasing the processing structure toward the semiconductor workpiece while polishing.

32. The method of claim 31, wherein the magnetically biasing results in applying a selected pressure to the surface of the workpiece.

33. The method of claim 31, wherein the magnetically biasing results in applying a selected pressure to a region of the surface of the workpiece.

34. The method of claim 31, wherein the magnetically biasing results in applying a selected pressure to a region of the surface of the workpiece while applying another selected pressure to another region of the surface of the workpiece.

35. The method of claim 31, further comprising touching the surface of the semiconductor workpiece with an electrical contact while polishing.

36. The method of claim 35, wherein at least come of the conductive material is selectively deposited on the surface of the semiconductor workpiece during polishing.

37. The method of claim 35, wherein at least come of the conductive material is removed from the surface of the semiconductor workpiece during polishing.

38. The method of claim 31, further comprising flowing processing solution onto the surface of the semiconductor workpiece during processing.

39. The method of claim 38, wherein the processing solution contains a copper electrolyte.

40. The method of claim 38, wherein the processing solution is an etching solution.

41. The method of claim 38, wherein the processing solution is in fluid contact with an electrode.

42. A system for processing a surface of a semiconductor workpiece, comprising:
a workpiece holder configured to hold the workpiece;
a processing structure having a processing surface, the processing structure positioned across from a surface of the workpiece;
a first magnetic structure attached the processing surface; and
a second magnetic structure is disposed across from the first magnetic structure so as to levitate the first magnetic structure and thereby biasing the processing surface towards the surface of the workpiece during processing.
